(19) United States
(12) Patent Application Publication
(10) Pub. No.: US 2010/0246080 A1
(43) Pub. Date: Sep. 30, 2010

(54) Intelligent fuse-holder

(75) Inventors: Edward Robert Nelson, San Jose, CA (US); Stephen Yeung, San Jose, CA (US)

Correspondence Address: ELIZABETH ANNE NEVIS, 1219 TORRANCE AVE., SUNNYVALE, CA, 94089, US

(73) Assignee: OptiSolar, Inc., a Delaware corporation, Hayward, CA (US)

(21) Appl. No.: 12/412,137

(22) Filed: Mar. 26, 2009

(51) Int. Cl. H02H 3/04; G08B 3/10; H05K 7/00; H02H 3/08

(52) U.S. Cl. 361/87; 340/384.7; 361/807

(57) ABSTRACT

In high-current electrical devices protected by fuses, additional performance data besides whether or not a fuse is blown is useful for diagnostics, repair, and preventing emerging failures from reaching a level that damages the device. An intelligent fuse-holder includes a built-in current sensor. The current sensor signals are passed through an A/D converter and analyzed by a microcontroller. Through an interface, a user can program the fuse-holder to periodically degauss the current sensor coil to improve performance or turn the sensor power off to conserve power. The user may also control various I/O signals carrying information about the fuse, the intelligent electronics, or the host board on which the fuse-holder is mounted.

### BACKGROUND

Many circuits fabricated on printed circuit boards (PCBs) benefit from a board-mounted fuse to protect the components from damage by power surges and other overcurrent conditions. However, conventional DIN and panel-mounted fuse-holders do not easily plug into a PCB. There are PCB-mounted fuse clips for a wide variety of fuses such as ¼AG, 5×20 mm, and automotive.

However, neither these simple fuse clips nor the non-PCB-compatible fuse holders include capabilities for measuring currents and using a microcontroller to calculate leakage current, saving power, and monitoring various external conditions that affect performance of the host board. Instead, designers must mount separate components on the host board to perform these functions. All these functions are related to energy efficiency, performance optimization, and damage prevention for the host board, which are useful in a wide variety of circuits. Building them into the host board separately takes design time and uses up space on the host board.

In addition, many conventional open-loop current sensors experience signal drift when operated over wide temperature ranges. Host boards that must operate in non-climate-controlled environments, such as those in remote communications or energy stations, often experience wide temperature ranges. To cope with these situations, designers need to include temperature-compensation circuits, which further increase design cost and use up more of the limited available space on the host board.

Therefore, a need exists for a next-generation fuse-holder that can accurately measure host-board current under a wide range of ambient conditions, alert users when important operating conditions change, and save power. Such a device would be even more useful if the functions were programmable to meet the monitoring needs of various types of host boards operating under various conditions.

### BRIEF SUMMARY

A need exists for a fuse-holder adapted to monitor current circulating on a host board. The Intelligent Fuse Holder (IFH) includes Hall-effect current sensors that interface to a microcontroller. A need exists for a fuse-holder adapted to monitor leakage current in the host board. The IFH includes dual current inputs and dual current outputs to collect the measurements necessary for calculating leakage current, and a microcontroller with instructions for automatically performing the calculations.

A need exists for maintaining the accuracy of the current sensors in the fuse-holder over extended operating time. The IFH includes a degauss coil which improves sensor performance by periodically neutralizing magnetic field build-up during operation.

A need exists for a fuse-holder that can alert users to a failure or problem that affects the current through the fuse. The IFH includes alerting components controlled by the microcontroller to communicate information to a user. The alerting components may be indicators, such as LEDs, on an easily visible surface of the IFH. They may also include audible signals or other signals transmitted through wires or over the air to a user's receiving device (such as a computer or mobile receiving device).

A need exists for a current-monitoring fuse-holder that is adaptable to a wide range of circuits and consumes only as much power as is necessary to perform the needed functions on the particular type of host board where it is used. The IFH microcontroller includes a built-in A/D converter and multiplexer unit, a programmable gain amplifier (PGA), a temperature sensor, programmable digital I/O and two digital-to-analog converters (DAC). The microcontroller scans and records the current sensor output by turning the sensor power on, degaussing the sensors to ensure accurate sensing, reading the sensor outputs, turning sensor power off when the measurement is complete, and recording the temperature from a temperature sensor that may be built-in. It will perform this measurement cycle at a user-programmable rate to minimize the power consumed by the current monitoring function. In addition, the IFH includes several high-current/high-voltage pins (the number depending on the current load and pin rating) and several low voltage pins to carry power or signals, as well as several programming pins for programming the microcontroller; all of these features enhance the IFH's versatility and adaptability.

A need exists for an intelligent fuse-holder that is compatible with existing standards. The IFH can operate through a standard serial interface (such as RS485) and utilize a standard protocol (such as Modbus) to allow the user to read both Hall-effect current sensors, control one or more I/O signals which may be used for alarm/warning indications, and set other user parameters. The IFH also mates to a host board via a PCB-mount socket, making it easy to install, remove and replace.

A need exists to minimize resulting waste and down-time after a fuse failure. When a fuse blows, the IFH can be quickly and safely removed or the fuse can be quickly ejected and replaced.

### BRIEF DESCRIPTION OF DRAWINGS

FIG. 1 is a conceptual diagram of the outside of the IFH showing an example of the indicators and connections.

FIG. 2 is a functional diagram of one embodiment of an IFH.

FIGS. 3a-3c show an approach to enabling IFHs to read protocol addresses based on the locations of the IFHs on the host board.

FIG.4 is an example flowchart of a microcontroller process in a preferred embodiment.

FIGS. 5a-5c illustrate example layouts of a fuse module, a programming module, and the manner in which the two modules connect to each other.

### DETAILED DESCRIPTION

The IFH communicates failures (such as blown fuses) and sub-failure problems (such as overcurrents that do not blow the fuse or temperatures exceeding a prescribed range) without requiring the user to apply test probes or otherwise disturb the host board. Multiple IFHs may be used on a single host board. The fuse and fuse-holder electronics are contained in a compact insulated housing that plugs into the host board via one or more convenient connectors. Indicators on the most easily visible surface of the housing change their appearance to indicate failures or problems. Alerts about failures or problems may also be sent to a user's receiving device (e.g. computer, mobile phone, personal digital organizer).

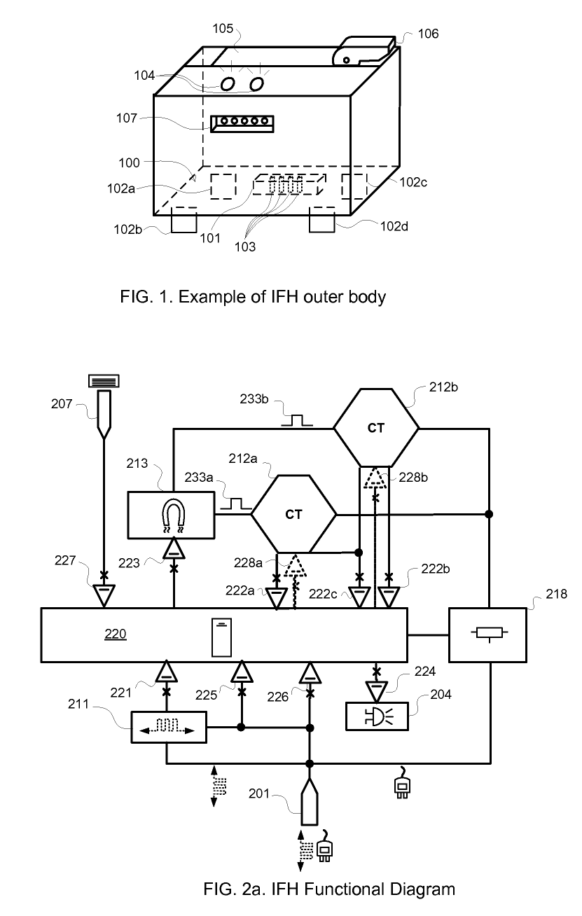

FIG. 1 is a conceptual diagram of one possible insulated housing for a preferred embodiment of the IFH. The housing may be made of plastic by an inexpensive, convenient method such as injection molding, but other insulating materials and manufacturing methods may also be used. The housing's connection surface 100 includes the operating connections to the host board. Connection features on connection surface 100 include high current/ high voltage connectors 102a-d and low-voltage power/signal pins 103. High-current/high-voltage connectors 102a and 102c connect to the source current, while high-current/high-voltage connectors 102b and 102d connect to the return current. Power/signal pins 103 may be built into a PCB-compatible connector 101, which may be a standard part or a custom design. Multiple IFHs may be mounted on a single host board. Other features are flexible in where they may be placed.

Alerting indicators 104 may be programmed to respond to conditions such as a blown fuse, excessive ground-fault current, or extreme temperature. If alerting indicators 104 are visual indicators, they are preferably placed where they can be easily seen while the board is operating. Here they are shown on the top, but other embodiments may mount them on a side surface of the IFH for boards that are more easily viewed edge-on during operation. If alerting indicators 104 send an audible signal, they need not be placed in an easily visible location. If alerting indicators 104 send signals to an electronic receiver, they may be placed anywhere where the signal will not be obstructed or interfere with host board operation. Fuse hatch lid 105, through which the fuse (omitted from this view for drawing clarity) is installed and replaced, and fuse ejector 106 that allows a user to open fuse hatch lid 105 and manually or mechanically eject a fuse, are preferably placed where a user can easily and safely reach them. Recessed programming port 107, which is only connected when the functions are being programmed, is shown on a side surface in the example figure but may be in any convenient location. For instance, in applications where programming should take place only when the IFH is disconnected, or only in a lab or factory rather than in the field, programming port 107 could be located on connection surface 100 to prevent mistaken access during operation. Where programming or retrieval of stored data will be done by a separate device while the IFH operates, the programming port may be located on an accessible surface but protected from accidental contact. Alternatively, power/signal port 201 could be adapted to handle the programming signals, enabling the IFH to be programmed by or through the host board.

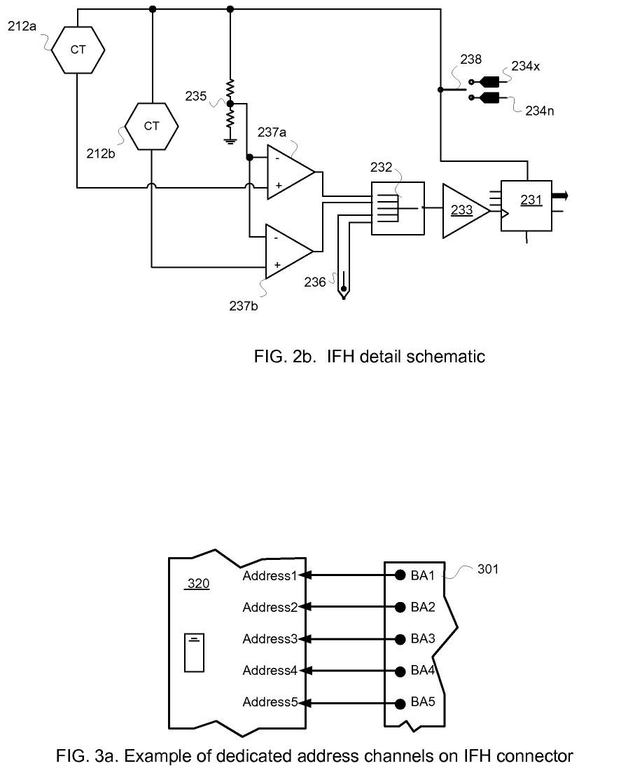

FIG. 2 is a functional diagram of one IFH embodiment. The IFH receives power and signals from the host board through power/signal port 201. Power/signal port 201 may carry, among other things:

1. Power for microcontroller logic

2. Power for degauss circuit

3. Signal/power ground

4. Serial interface signals

5. Bus protocol address

Incoming power goes through voltage regulator 218, which adapts the supply voltage to an optimal range for powering microcontroller 220. Reset signal 225 and address signal 226 go directly to microcontroller 220 from power/signal port 201. Communication signal 221 passes to and from microcontroller 220 through a communications module, shown here as transceiver 211 but also realizable as a separate transmitter and receiver. Microcontroller 220 also receives programming signals 227 through programming port 207 when a designer or user programs operating code and parameters into the IFH. Depending on its configuration, programming port 207 can simply accept input code from an external programming device, or also allow retrieval of stored data by an external device. Alternatively, power/signal port 201 could be adapted to handle the programming signals, enabling the IFH to be programmed by or through the host board.

Source-current sensor 212a measures source current in the host board and sends source-current measurement 222a to microcontroller 220. Return-current sensor 212a measures return current in the host board and sends return-current measurement 222b to microcontroller 220. (Neither the host board nor the high-current connections are shown in this figure). Differential measurement 222c is a comparison of measurements 222a and 222b calculated by microcontroller 220. If 222a and 222b are different in magnitude, the host board is leaking current to ground and the difference between them is nonzero. Enhancements may include averaging several current measurements, correcting the current measurement using temperature data if available, and detecting trends in current over time. This system can also detect the arcing that occurs in some defective fuses. Optionally, the system can generate a particular alert when the fluctuation characteristic of an arcing fuse is detected.

One problem endemic to Hall-effect current sensors is that magnetic fields build up around the coil, affecting the sensed-current reading and decreasing its accuracy. To solve this problem, microcontroller 220's digital output includes degauss controls 223, which causes degauss circuit 213 to generate degauss pulses 233a and 233b. The degauss pulses 233a and 233b remove any built-up magnetic fields from the coils of current sensors 212a and 212b, respectively. Preferably, the degauss coils may be operated by a single double-capacity degauss circuit to reduce the component count. Degauss cycles may be generated either periodically or when triggered by a predetermined signal or calculation result. After delivering the degauss pulse(s), degauss circuit 213 deactivates so normal operation can continue. A delay may be built in between degaussing and measuring current to prevent any tail-end effects of the degauss pulse from affecting the measurements.

To compensate for any signal drift of the current sensors with temperature, microcontroller 220 may also collect data from a temperature sensor, either built-in or external. A stored look-up table of temperatures and corresponding compensation values can be used to adjust the reading taken from the current sensor.

When a predetermined triggering event occurs, such as a blown fuse, ground fault, overcurrent, or undercurrent, microcontroller 220 sends alerting signals 224 to activate the corresponding alerting indicators 204. Temperature sensor 236 may optionally also trigger an alert when the temperature varies outside a predetermined optimal operating range, via microcontroller 220's accessing stored the minimum and maximum operating temperatures from a look-up table and comparing them to the most recently measured temperature. The alerts enable a user to immediately identify a problem without connecting test equipment to the host board, saving a significant fraction of potential down-time and reducing operating costs. The alerting indicators can be visual indicators (for example, LEDs or small displays) built into the IFH housing, audio alarms built into the IFH or the host board, or messages from internal transceiver 211 or an external transceiver on the host board to a user's computer, phone, or mobile receiving device. Optionally, a wireless transceiver may be used.

In a preferred embodiment, the alerting functions are fully programmable in the operating protocol through programming port 207; for instance, the user could program an alert to be triggered when the fuse has experienced current greater than 12.8A more than 10 times. More alerting options are possible when multiple IFHs are used on the same host board or connected host boards and their transceivers 211 can communicate with each other. For instance, the user could program microcontroller 220 to send an alert when the programmed IFH's current is low compared to other IFHs in an assembly.

Power saving is important to the operation of many host boards. Therefore, the IFH should use only as much power as necessary to perform its intended function. To save power, microcontroller 220 can command the current sensors to turn on for a measurement and off after a measurement using optional power-save mode signals 228a and 228b. This can reduce the power required by as much as 50%. Reset signal 225 may be used for entering and exiting power-save mode as well as powering the entire IFH up and down.

FIG. 2b is a detail schematic of some of the subcomponents that may either be built into or connected to microcontroller 220. An A/D converter (ADC) 231 with a multiplexer 232 and programmable gain amplifier (PGA) 233, is preferably built into microcontroller 220, but may be a separate component. The negative side of each differential amplifier 237a and 237b receiving measurements from a current sensor 212a or 212b is preferably connected to an external voltage divider 235. The voltage divider may use the same voltage source as the current sensors. Temperature measurement signals from a temperature sensor 236 may be input to multiplexer 232 as well as current measurement signals coming through differential amplifiers 237a and 237b. A voltage reference for ADC 231 may be built into microcontroller 220 or external. In some situations, an external reference voltage may be more accurate. Here, either external voltage reference 234x or internal voltage reference 234n may be selected by setting switch 238.

The analog inputs to ADC 231 may be either single-ended or differential. Differential analog inputs are preferred because they increase accuracy. Differential A/D enables automatic compensation of current-sensor output variations resulting from variations in supplied power. Differential A/D also rejects common noise from both signal and power sources.

The serial interfaces for the programming port and operating power/signal port are preferably efficient and industry-standard. For example, a J-tag or ICP may be suitable for the programming port, depending on the particular functions desired. Optionally using an RS485 serial interface for the power/signal port enables interconnection of multiple IFHs on a single half-duplex communication line, so that the IFHs can communicate and compare data to identify and locate host-board problems. Preferably, the power/signal port serial interface supports a single baud rate of at least 1200 bps and operates under a convenient protocol, such as Modbus (an open-source protocol that is widely used in process control) or DNP. The protocol is primarily chosen for its ability to support desired IFH functions. The functions can include:
1. Changing the rate at which the IFH current sensors take measurements
2. Changing the Excessive Ground Current alerting threshold
3. Requesting minimum, maximum, or average current-sensor readings since last scan
4. Initiating current-sensor calibrations
5. Requesting IFH serial number and other manufacturing data
6. Requesting the version identifier for the IFH firmware currently running on the microcontroller
7. Initiating and changing triggering conditions for user-defined alerts
8. Testing the functionality of alerts or surge-protection features

In enhanced versions, retrieving identification and other data from chips on the host board through an interface such as I2c, SPI, or I-wire.

Implementation of some protocols (including Modbus) requires that each IFH have a protocol address. Any method of assigning addresses may be used. However, on a host board with multiple IFHs, localized problems can be quickly located for faster repair and reduced downtime if the IFH addresses are based on IFH location on the host board and are retrievable without disrupting IFH operation. If each of the IFH host board connectors has a unique address pinout, the IFHs can use this to “read” their locations directly off the host board. With this capability, the IFHs may be replaced or interchanged randomly and still always have addresses based on their location on the host board.

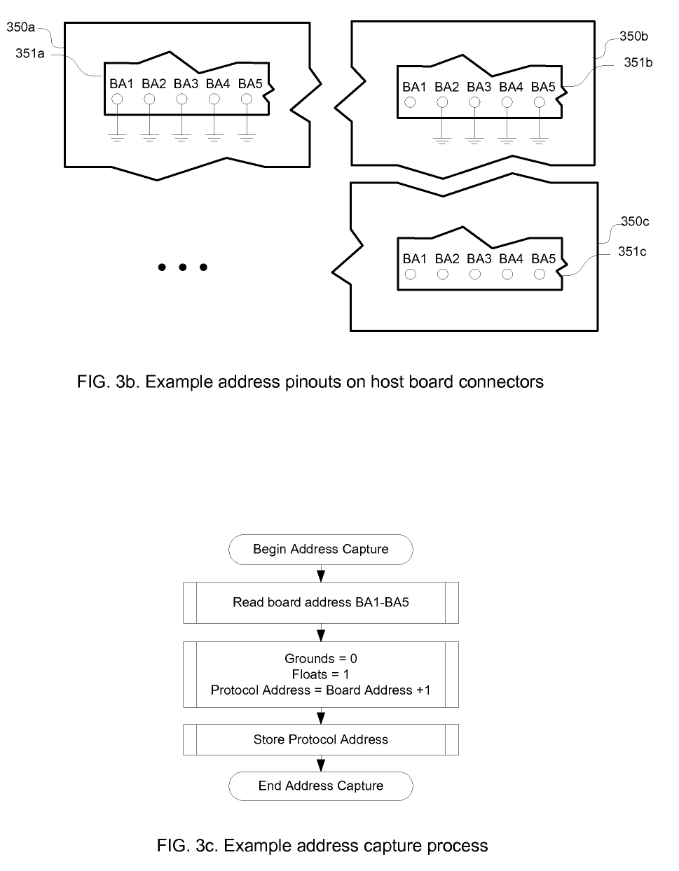

FIGS. 3a-3c illustrate one possible approach to a host board conferring location-based addresses to multiple IFHs through the pinout configuration of individual IFH connectors. For clarity, only the parts of the connectors dedicated to address detection are shown.

FIG. 3a shows part of a power/signal connector 301 and part of a microcontroller 320 in an IFH. In this example, five channels BA1-BA5 in power/signal connector 301 are dedicated to address detection. If each channel carries 1 bit of data, this configuration allows 2⁵=32 different addresses. (More or fewer addresses may be enabled by other configurations). Each IFH address channel BA1-BA5 has a dedicated input/output point in microcontroller 320, which includes a weak pull-up on each BAx signal.

FIG. 3b shows examples of address-readable connector pinouts on the host board. At various locations 350a-350c on the host board are mating connectors 351 a-c, which mate with IFH power-signal connectors configured like connector 301 in FIG. 3a. Mating connector 351a at host-board location 350a has all the BA1-BA5 pinout connections grounded (board address 0). Mating connector 351b at location 350b has BA1 floating and BA2-BA5 grounded (board address 1). Mating connector 351a at host-board location 350a has all the BA1-BA5 pinout connections floating (board address 31).

FIG. 3c is an example flowchart of the process by which the IFHs recognize their location-based addresses. When the host board is powered on, the microcontroller (320 in FIG. 3a) reads BA1-BA5 applying a weak pull-up, assigns zero to grounded signals and 1 to floating signals and computes the binary value, then adds 1 to the resulting decimal-converted value to determine the protocol address. Thus the IFH connected to connector 351a in FIG. 3b would have protocol address 001, the IFH connected to connector 351b would have protocol address 002, and the IFH connected to connector 351b would have protocol address 032. This eliminates the need to pre-program IFH addresses, and thereby the need to mark and sort IFHs to ensure positioning them on the host board according to those addresses. Therefore, even if an IFH must be immediately replaced with another one when a fuse blows and the blown fuse replaced offline, the new IFH will automatically have the same location-based address as the replaced one.

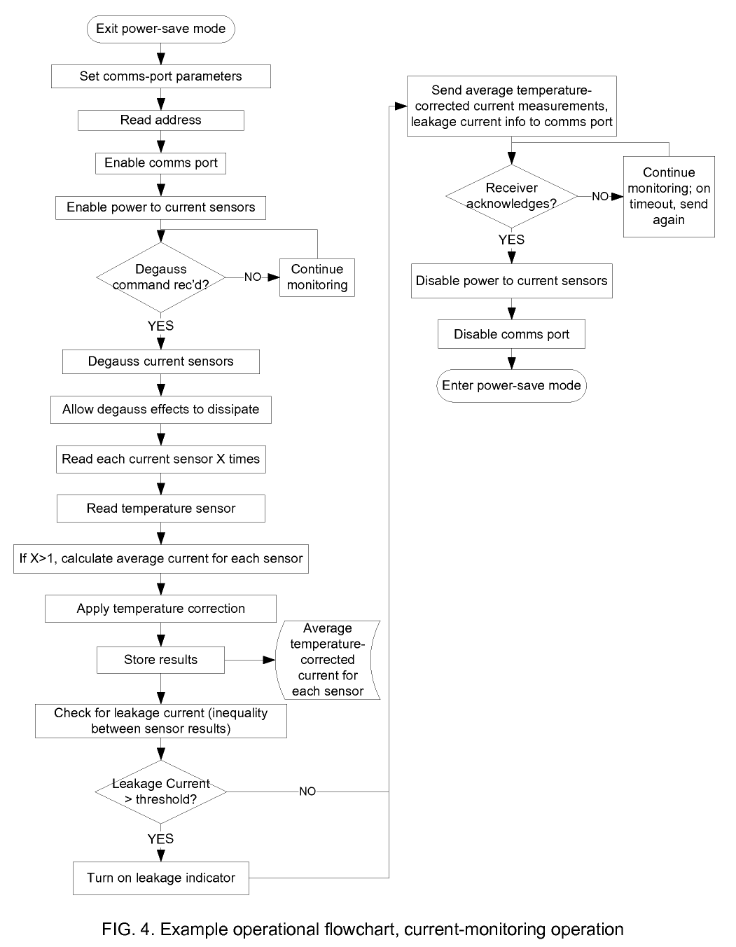

FIG. 4 is an example flowchart of a microcontroller process in a preferred embodiment that includes power saving. At programmed intervals, (or, in enhanced versions, responsive to triggering signals from the host board that come through the communications port), the microcontroller turns on and, if necessary, degausses the current sensors. The microcontroller then sends “measure” commands to the current sensors (and optionally a temperature sensor) and analyzes the signals (optionally taking several measurements and averaging them). If a current leakage (ground fault) condition is detected from the measurements (when the difference between the source and return currents exceeds the predetermined threshold), the microcontroller activates the ground-fault alerting indicator. Optionally, the microcontroller can store successive measurements and measure trends, or store a history of alerts, for performance reporting. The data can be retrieved through the programming port (if the programming port is optionally configured for user interface), sent from the transceiver to a remote receiver, or accesses through part of the host board with a communications connection to the IFH. When a measurement is complete, the current sensors (and optionally other components) are deactivated to save power until the next measurement occasion.

In one embodiment, the IFH circuitry is divided into two modules. The division can be advantageous when, for example, the circuits are fabricated on PCBs; the blocks can be arranged on separate PCBs, which can be stacked or placed side-by-side inside the housing to save lateral space if the host board has components that do not fit under the bottom of the IFH housing. Analog board layout techniques help insure accuracy such as ground planes, short traces, ferrite beads etc. One possible division is into a fuse module and a programming module.

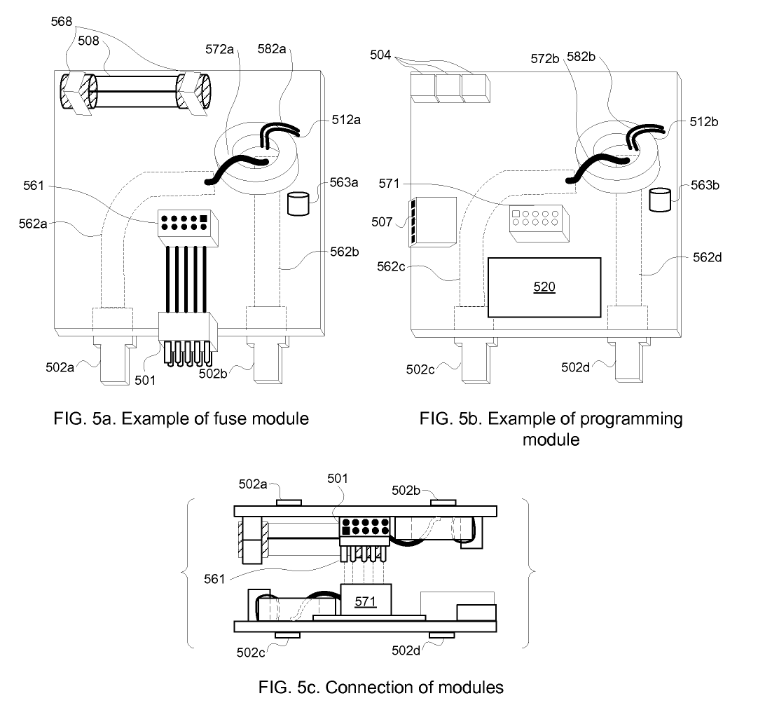

FIG. 5a is an example diagram of a fuse module. Some of the components and connections are omitted for clarity. The fuse module includes the fuse 508 removably mounted in fuse mount 568. Fuse mount 568, shown here as a simple pair of fuse clips, may also be part of a spring-loaded fuse ejector. High-current connectors 502a and 502b, illustrated for the example here as quick-connect tabs, both connect to the source or the return current of the host board (not shown). The current travels through high-current traces 562a and 562b to jumper 572a, where the current passes through Hall-effect current sensor 512a to be measured. Degauss coils 582a are included to degauss current sensor 512a. To save space while allowing high-current traces 561a and 561b to be wide enough to carry the high current, high-current connectors 502a and 502b are mounted on the back of the fuse-module board in this example. Main power/signal connector 501 is also mounted on the fuse module in this example, to connect with a mating connector on the host board (not shown). Connector 501 delivers its power and signals to interface connector 561 as well as to any components on the fuse module that use the power and signals. Mechanically thick parts such as connector 501, fuse 508, current sensor 512a, and degauss capacitor 563a are arranged for non-interference with thick parts on the programming module. The exception is interface connector 561, which lines up with its mating interface connector on the programming module. Various other electronics, including surface-mount components, may be arranged in the remaining space according to analog layout principles. Preferably, to minimize module size and maximize high-current trace width, any components that take up space on both sides of the board are located close to the center or near the fuse edge of this board.

FIG. 5b is an example a programming module; for clarity, only some of the components and traces are shown. In this example, programming port 507 (which will be recessed in the housing to protect it during operation), microprocessor 520, and alerting indicators 504 are located on the programming module. This enables some programming functions and tests to be performed on the programming module in isolation, using fixtures rather than needing the entire IFH to be assembled. High-current connectors 502c and 502d connect to the return or the source current of the host board (not shown), whichever current is not engaged by the fuse module. The current travels through high-current traces 562c and 562d to jumper 572b, where the current passes through Hall-effect current sensor 512b to be measured. Degauss coils 582a are included to degauss current sensor 512a. To save space while allowing high-current traces 561a and 561b to be wide enough to carry the high current, high-current connectors 502a and 502b are mounted on the back of the fuse-module board in this example. In the programming module, locating the high-current/high-voltage traces on the back of the module serves to isolate them from the low-voltage traces (not shown) carrying sensitive signals to and from programming port 507. Mating power/signal interface connector 571 mates with interface connector 561 on the fuse module. In this example, connector 571 carries power and signals from the fuse module to components using them on the programming module.

FIG. 5c is an exploded view showing how the fuse module and programming module of this example are connected together. Interface connector 561 mates with mating interface connector 571. High-current connectors 502a-d, and their connected traces (not shown in this view) are on the outside surfaces of the assembly, and the bulky, mechanically vulnerable parts of each module are between the boards. Standoffs (not shown) can be added for mechanical ruggedness and electrical isolation of the parts from the respective modules that face each other when the IFH is assembled.

Multiple other configurations are possible. For instance, if accessing the fuse in a direction perpendicular to the fuse module is more important than having the indicators reside on the programming module for feedback while programming or debugging, the indicators can be mounted beside the fuse on the fuse module and part of the programming-module board may be cut away for unobstructed access to the fuse.

Only the claims, rather than the specification, abstract, or drawings, are intended to limit the scope of the subject matter of this document.

1. An intelligent fuse-holder to hold a fuse for a host board, comprising:
an electromechanical holder for a fuse,
a current sensor configured to monitor source current circulating in the host board,
a microcontroller configured to read and analyze measurements from the current sensor,
an alerting indicator configured to generate alerts when the microcontroller detects a problem in the analyzed measurements, and
an insulated housing containing the holder, current sensor, microcontroller, and alerting indicator, attached to a high-current connection to the host board and a power/signal port connection to the host board.

2. The fuse-holder of claim 1, further comprising a degaussing circuit configured to preserve current-sensor accuracy by removing unwanted magnetic fields.

3. The fuse-holder of claim 1, further comprising a return-current sensor configured to monitor return current circulating in the host board, where the microcontroller detects a ground fault when the difference between the source current and the return current exceeds a predetermined threshold.

4. The fuse-holder of claim 1, where the traces between the current sensor and the high-current connector are electrically insulated from the microcontroller by being located on the opposite side of an internal IFH circuit board from the microcontroller.

5. The fuse-holder of claim 1, further comprising a programming port configured to transmit parameters and operating code between the microcontroller and an external user interface device.

6. The fuse-holder of claim 5, where the programming port is also configured to enable retrieval of stored data to an external device.

7. The fuse-holder of claim 5, where the functions of the alerting indicator are user-programmable through the programming port.

8. The fuse-holder of claim 1, where the microcontroller comprises at least one of:
an analog-to-digital converter,
a multiplexer,
a programmable-gain amplifier,
a voltage references, and
a temperature sensor.

9. The fuse-holder of claim 8, where analog inputs converted to digital signals comprise at least one differential analog input.

10. The fuse-holder of claim 8, further comprising a voltage divider connected to an input operational amplifier receiving a current measurement signal from the current sensor.

11. The fuse-holder of claim 1, where the detected problems activating an alert indicator comprise at least one of:
a blown fuse,
an overcurrent,
an undercurrent,
a ground fault,
an over-voltage,
an under-voltage,
an arc in a defective fuse, and
a temperature outside the host board's optimal operating range.

12. The fuse-holder of claim 1, where the alerting indicator generates alerts by producing at least one of:
a visible signal,
an audible signal, and
a signal detectable by an external sensor.

13. The fuse-holder of claim 1, where the power/signal port connection is configured to transmit at least one of:
logic power for the microcontroller,
power for degaussing the current sensor,
connection to ground,
a serial interface signal, and
a module protocol address.

14. The fuse-holder of claim 1, further comprising a transmitter and receiver configured to pass communication signals between the microcontroller and the host board through the power/signal port connection.

15. The fuse-holder of claim 14, where the power/signal port connection allows communication between multiple fuse-holders on a common communication line.

16. The fuse-holder of claim 1, further comprising a voltage regulator connected between the power/signal connection and the microcontroller, where the voltage regulator is configured to adapt the supply voltage to an optimal operating range of the microcontroller.

17. A method of protecting a high-current host board from electrical damage, comprising:
connecting a replaceable fuse in a current path of the host board,
monitoring a source current circulating in the host circuit board,
analyzing the monitored current to detect present or developing problems in the host circuit board, and
activating an alert when a problem is detected,
where the connecting of the fuse, monitoring, analyzing, and activating of the alert are performed by components of an interchangeable, self-contained intelligent fuse-holder.

18. The method of claim 17, further comprising
monitoring a return current circulating in the host board, and
detecting a ground fault when the difference between the source current and the return current exceeds a predetermined threshold.

19. The method of claim 17, further comprising at least one of:
degaussing a current sensor to preserve current measurement accuracy,
deactivating current-monitoring components between measurement events to save power,
sensing a temperature substantially near the host circuit board and comparing the sensed temperature to an optimum operating temperature of the host board,
storing time-connected data on at least one of monitored current and activated alerts, and
storing and retrieving identifying information on the intelligent fuse-holder's hardware, firmware, and/or software.

20. The method of claim 17, further comprising:
connecting multiple intelligent fuse-holders to the same host circuit board, and
assigning a unique module protocol address to each of the multiple intelligent fuse-holders,
where the module address includes information related to the location of each of the intelligent fuse-holders on the host circuit board.
